(19) United States
(12) Patent Application Publication
(10) Pub. No.: US 2026/0304762 A1
(43) Pub. Date: Oct. 1, 2026

(54) SEMICONDUCTOR DEVICE AND FABRICATION METHODS THEREOF

(71) Applicant: Yangtze Memory Technologies Co., Ltd., Wuhan (CN)

(72) Inventors: Cuicui KONG, Wuhan (CN); Wenxi ZHOU, Wuhan (CN); Zhiyao PENG, Wuhan (CN); Linchun WU, Wuhan (CN); Dingding SHEN, Wuhan (CN)

(21) Appl. No.: 19/259,235

(22) Filed: Jul. 3, 2025

(30) Foreign Application Priority Data
Mar. 28, 2025 (CN) 202510386529.X

(51) Int. Cl. H10B 43/10; H10B 41/10

(52) U.S. Cl. CPC H10B 43/10; H10B 41/10

(57) ABSTRACT

Methods, devices, systems, and techniques for managing isolating structures in semiconductor devices are provided. In one aspect, a semiconductor device includes a first memory block having a first stack of first insulating layers and first dielectric layers alternating with each other along a first direction and a second memory block having a second stack of second insulating layers and second dielectric layers alternating with each other along the first direction. The semiconductor device also includes a first separation structure between the first memory block and the second memory block, where the first separation structure extends along a second direction perpendicular to the first direction, and where a first portion of the first separation structure is in contact with the first stack of the first memory block and the second stack of the second memory block along a third direction perpendicular to the first direction and the second direction.

### CROSS-REFERENCE TO RELATED APPLICATIONS

This application claims priority to Chinese Patent Application No. 202510386529.X, filed on Mar. 28, 2025, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes a first memory block having a first stack of first insulating layers and first dielectric layers alternating with each other along a first direction. The semiconductor device also includes a second memory block having a second stack of second insulating layers and second dielectric layers alternating with each other along the first direction; and a first separation structure between the first memory block and the second memory block, where the first separation structure extends along a second direction perpendicular to the first direction, and where a first portion of the first separation structure is in contact with the first stack of the first memory block and the second stack of the second memory block along a third direction perpendicular to the first direction and the second direction.

In some implementations, the first memory block further includes a third stack of the first insulating layers and first conductive layers alternating with each other along the first direction, where the second memory block further includes a fourth stack of the second insulating layers and second conductive layers alternating with each other along the first direction, and where the first stack, the first separation structure, and the second stack are between the third stack of the first memory block and the fourth stack of the second memory block along the third direction.

In some implementations, the first portion of the first separation structure comprises a first conductive material, wherein the first conductive material is in contact with the first stack of the first memory block and the second stack of the second memory block.

In some implementations, the semiconductor device further includes a third memory block having a fifth stack of third insulating layers and third conductive layers alternating with each other along the first direction, and a sixth stack of the third insulating layers and third dielectric layers stacked on top of each other along the first direction; and a second separation structure extending along the second direction, where the second separation structure is between the first memory block and the third memory block.

In some implementations, the semiconductor device further includes a third separation structure extending along the third direction, where the third separation structure is in contact with the first memory block, the second memory block, the third memory block, the second separation structure, and a second portion of the first separation structure along the second direction.

In some implementations, the second separation structure comprises a second conductive material surrounded by a first outer layer, and where a first portion of the third separation structure comprises the second conductive material surrounded by a second outer layer.

In some implementations, the second separation structure includes a first isolation structure extending along the second direction.

In some implementations, the first separation structure includes a second isolation structure extending along the second direction, where the second isolation structure is between the first portion and a second portion of the first separation structure, and where a length of the second isolation structure is no greater than a length of the first isolation structure along the second direction.

In some implementations, the third memory block further includes a seventh stack of the third insulating layers and fourth conductive layers alternating with each other along the first direction, where the sixth stack is between the fifth stack and the seventh stack along the second direction, and where the fifth stack, the sixth stack and the seventh stack are in contact with the first isolation structure.

In some implementations, the third separation structure includes at least two third isolation structures extending along the third direction, and where each of the first stack and the second stack is in contact with a corresponding third isolation structure of the at least two third isolation structures along the second direction.

In some implementations, a second portion of the third separation structure includes a third conductive material, the second portion of the third separation structure is between two adjacent third isolation structures in the first memory block and the second memory block along the third direction where the first stack and the second stack are in contact with the third conductive material along the second direction.

In some implementations, the second portion of the first separation structure includes a fourth conductive material, where the fourth conductive material is in contact with the first stack of the first memory block and the second stack of the second memory block.

In some implementations, the second portion of the first separation structure is between the first stack and the second stack along the third direction.

Another aspect of the present disclosure features a method of forming a semiconductor device. The method includes forming a first memory block having a first stack of first insulating layers and first dielectric layers alternating with each other along a first direction; forming a second memory block having second stack of second insulating layers and second dielectric layers alternating with each other along the first direction; and forming a first separation structure between the first memory block and the second memory block, where the first separation structure extends along a second direction perpendicular to the first direction, and where a first portion of the first separation structure is in contact with the first stack of the first memory block and the second stack of the second memory block along a third direction perpendicular to the first direction and the second direction.

In some implementations, the method further includes forming a third memory block having a fifth stack of third insulating layers and third conductive layers alternating with each other along the first direction, and a sixth stack of the third insulating layers and third dielectric layers stacked on top of each other along the first direction; and forming a second separation structure extending along the second direction, where the second separation structure is between the first memory block and the third memory block.

In some implementations, the method further includes providing a first block structure corresponding to the first memory block, a second block structure corresponding to the second memory block, and a third block structure corresponding to the third memory block, the first block structure, the second block structure, and the third block structure including alternating dielectric layers and isolating layers, where the first block structure is between the second block structure and the third block structure along the third direction, where the first block structure and the second block structure are separated by a first semiconductor structure, and where the first block structure and the third block structure are separated by a second semiconductor structure; forming a second isolation structure extending along the second direction in the first semiconductor structure; forming a first isolation structure extending along the second direction in the second semiconductor structure; removing a first portion of the second semiconductor structure to form a first trench, where the first portion of the second semiconductor structure is in contact with a first end of the first isolation structure along the second direction; filling an etching solution into the first trench to etch a portion of the dielectric layers of the first block structure and a portion of the dielectric layers of the third block structure to form a first space; filling a fifth conductive material in the first space; and filling the first trench with a second conductive material surrounded by a dielectric material.

In some implementations, the method includes forming a third semiconductor structure extending along the third direction, where the third semiconductor structure is in contact with the first block structure, the second block structure, the third block structure, the first semiconductor structure, and a second portion of the second semiconductor structure along the second direction.

In some implementations, the method includes etching the third semiconductor structure, the second portion of the second semiconductor structure in contact with the third semiconductor structure, and a portion of the first semiconductor structure in contact with the third semiconductor structure to form a second trench; filling an etching solution into the second trench to etch a portion of the dielectric layers of the first block structure and a portion of the dielectric layers of the third block structure to form a second space; filling the fifth conductive material in the second space; and filling the second trench with the second conductive material surrounded by the dielectric material.

In some implementations, the method includes forming at least two third isolation structures extending along the third direction in the third semiconductor structure, where each of the first block structure and the second block structure is in contact with a corresponding third isolation structure of the at least two third isolation structures along the second direction; etching a portion of the third semiconductor structure and the second portion of the second semiconductor structure to form a third trench; filling an etching solution into the third trench to etch a portion of the dielectric layers of the first block structure and a portion of the dielectric layers of the third block structure to form a third space; filling the fifth conductive material in the third space; and filling the third trench with the second conductive material surrounded by the dielectric material.

A further aspect of the present disclosure features a memory system. The memory system includes a memory device; and a memory controller coupled to the memory device and configured to control the memory device, where the memory device includes a first memory block having a first stack of first insulating layers and first dielectric layers alternating with each other along a first direction; a second memory block having second stack of second insulating layers and second dielectric layers alternating with each other along the first direction; and a first separation structure between the first memory block and the second memory block, where the first separation structure extends along a second direction perpendicular to the first direction, and where a first portion of the first separation structure is in contact with the first stack of the first memory block and the second stack of the second memory block along a third direction perpendicular to the first direction and the second direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIG. 1A illustrates a block diagram of an example semiconductor device.

FIG. 1B illustrates a top view of an example semiconductor device.

FIG. 1C illustrates a cross-section view of an example semiconductor device.

FIGS. 2A-2C illustrate top views of example semiconductor devices.

FIG. 3A-3L show top views of structures of a 3D semiconductor device of FIG. 2A at various stages of a fabrication process.

FIG. 4A-4L show top views of structures of a 3D semiconductor device of FIG. 2C at various stages of a fabrication process.

FIG. 5 illustrates a flow chart of an example process of manufacturing a semiconductor device.

FIG. 6 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the demand for cheaper memory devices with higher density, a memory device (e.g., a 3D NAND flash memory) can be formed with multiple planes of blocks of memory cell arrays adjacent to each other. Shrinking second region between two adjacent planes is necessary to increase core capacity of the memory device. However, this shrinking may pose challenges during device operation due to coupling effect between the two adjacent planes. In other words, the leakage current of one plane may affect program, read, and erase operations of other planes adjacent to it. The increasing number of stacked memory cells further deteriorates the coupling effect between two adjacent planes of blocks of memory cell arrays. Therefore, a second region that can solve the aforementioned issues is desirable.

In one or more implementations of the present disclosure, an example semiconductor device is provided. The semiconductor device includes a first memory block having a first stack of first insulating layers and first dielectric layers alternating with each other along a first direction and a second memory block having a second stack of second insulating layers and second dielectric layers alternating with each other along the first direction. The semiconductor device also includes a first separation structure between the first memory block and the second memory block, where the first separation structure extends along a second direction perpendicular to the first direction, and where a first portion of the first separation structure is in contact with the first stack of the first memory block and the second stack of the second memory block along a third direction perpendicular to the first direction and the second direction.

Implementations of the present disclosure can provide one or more of the following technical advantages and/or benefits. First, second regions between two adjacent planes of the memory device include at least two dummy blocks. The two dummy blocks are separated by a separation structure and include two stacks of alternating insulating and dielectric materials. The separation structure and the two stacks of alternating insulating and dielectric materials of the dummy blocks are configured to electrically isolate core blocks of the two adjacent planes of the memory device, reducing the coupling effect of the core blocks. In other words, the dummy blocks in the second region of the two planes ensure individual control of the core blocks in each plane. Second, the dummy blocks in the second region between the two adjacent planes of the memory device include more dielectric material compared to the core blocks. The high ratio of dielectric material in the second region of the two adjacent planes reduce the leakage current between the core blocks of the two adjacent planes. In other words, the high ratio of dielectric material in the second region reduces a ratio of the conductive material in the dummy block which reduces coupling effect between the two planes. Third, the dummy blocks can be fabricated alongside the core blocks of the memory device, which simplifies the fabrication process and reduces fabrication costs.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

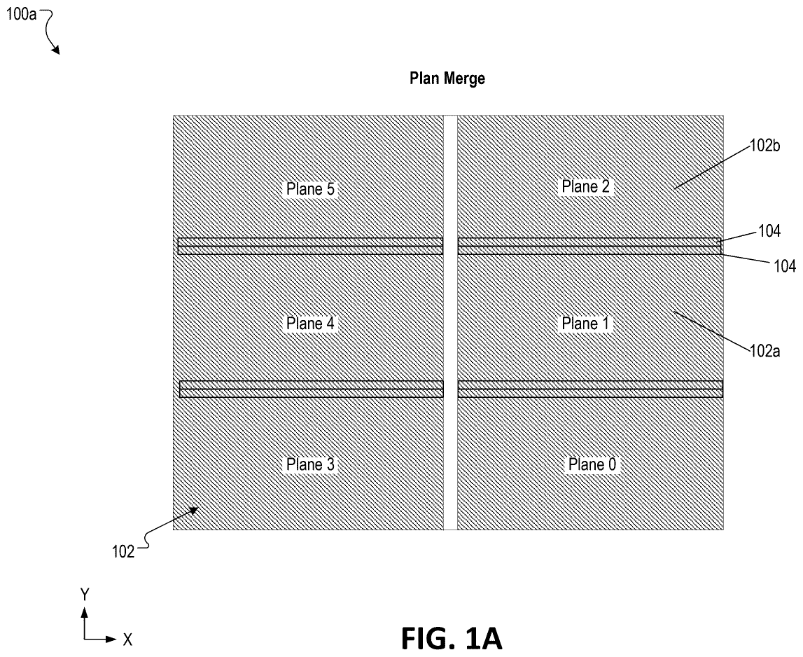

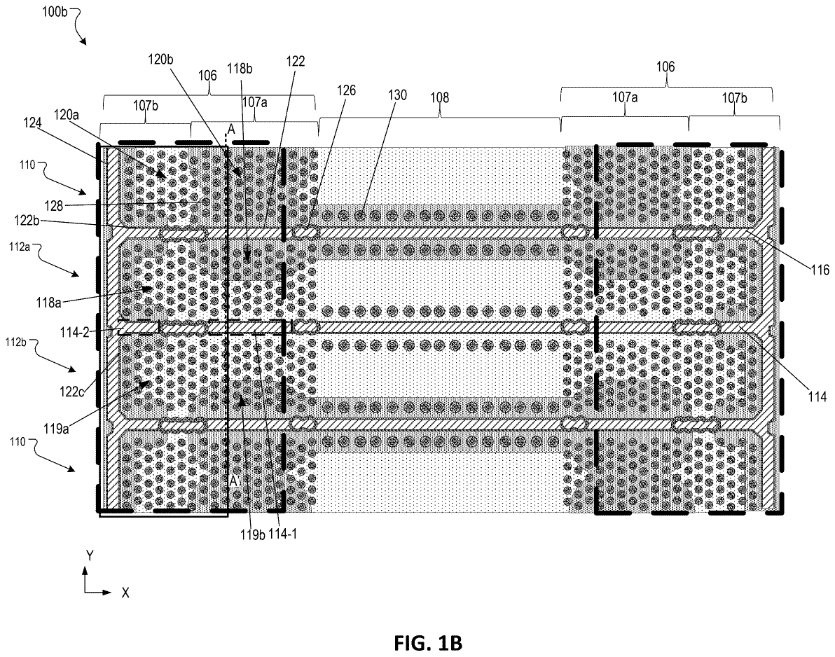

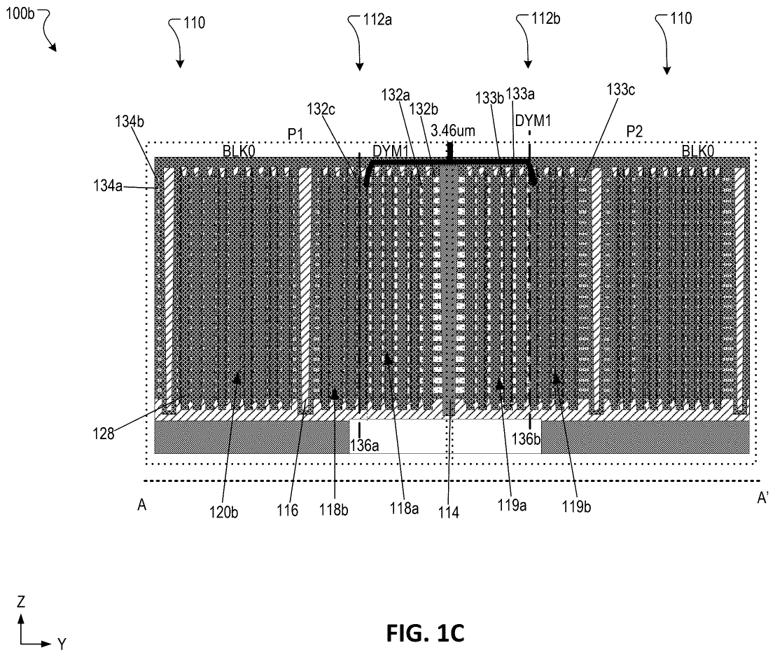

It is noted that X, Y, and Z axes (also referred to as X, Y, and Z directions) are included in FIG. 1A-1C to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a block diagram of an example semiconductor device 100a. As shown in FIG. 1A, the semiconductor device 100a can include one or more planes 102. Each of the planes 102 of the semiconductor device 100a can include a plurality of blocks of the memory arrays. In some implementations, the memory array can include three-dimensional (3D) NAND memory devices. As shown in FIG. 1A, each of the planes 102 of the semiconductor device 100a also includes a dummy block 104 at an edge of the plane 102. Two adjacent planes 102 are connected through dummy blocks 104 of the two adjacent planes 102. It is understood that the example semiconductor device 100a as shown in FIG. 1A is for illustration purpose and is not intended to be construed in a limiting sense. For example, the semiconductor device 100a can include any number of planes 102 that can have any suitable arrangements.

FIG. 1B illustrates a top view of an example semiconductor device 100b. In some implementations, the semiconductor device 100b can be a memory device, such as a three-dimensional (3D) NAND memory device. In some implementations, the semiconductor device 100b can be a portion of the two adjacent planes 102 of the semiconductor device 100a of FIG. 1A. The semiconductor device 100b can include one or more first regions 106 and one or more second regions 108 configured to provide conductive connections for the one or more first regions 106. In some implementations, as shown in FIG. 1B, the semiconductor device 100b includes two first regions 106 and a second region 108 between the first regions 106 along a first horizontal direction (e.g., the X direction). It is understood that the example in FIG. 1B is for illustration purpose and is not intended to be construed in a limiting sense. In practice, any suitable arrangement of various regions in the semiconductor device 100a can be applied. In some instances, the semiconductor device 100a can have two second regions 108 and a first region 106 arranged between the two second regions 108 along the X direction. In some other instances, the semiconductor device 100a can have one first region 106 and a second region 108 adjacent to the two first regions 106 along the X direction.

As shown in FIG. 1B, the semiconductor device 100b can include a plurality of core blocks 110 and two dummy blocks 112a and 112b. The two dummy blocks 112a and 112b are between the plurality of core blocks 110 along a second horizontal direction (e.g., the Y direction) perpendicular to the X direction. In some implementations, the dummy block 112a is on a side of the plane 102a of the semiconductor device 100a and the dummy block 112b is on a side of the plane 102b of the semiconductor device 100a. The sides of the plane102a and the side of the plane 102b are connected by the dummy blocks 112a and 112b along the Y direction.

As shown in FIG. 1B, the dummy blocks 112a and 112b are separated by a first separation structure 114. Each of the dummy blocks 112a and 112b are separated from a corresponding core block 110 by a corresponding second separation structure 116. For example, as shown in FIG. 1B, the dummy block 112a is between the dummy block 112b and the corresponding core block 110 along the Y direction. The dummy block 112a is separated with the dummy block 112b by the first separation structure 114 and the dummy block 112a is separated with the corresponding core block 110 by the second separation structure 116 along the Y direction. In some implementations, as shown in FIG. 1B, the dummy blocks 112a and 112b and the core blocks 110 include one second region 108 between two first regions 106 along a second horizontal direction (e.g., the X direction) perpendicular to the Y direction. The first separation structure 114 and the second separation structure 116 extend through the second region 108 along the X direction.

Each of the first regions 106 of the dummy block 112a has a stack 118a of first insulating layers (e.g., the first insulating layers 132a of FIG. 1C) and first dielectric layers (e.g., the first dielectric layers 132b of FIG. 1C) alternating with each other along a vertical direction (e.g., the Z direction). Each of the first regions 106 of the dummy block 112b has a stack 119a of second insulating layers (e.g., the second insulating layers 133a of FIG. 1C) and second dielectric layers (e.g., the second dielectric layers 133b of FIG. 1C) alternating with each other along the Z direction. In some implementations, the first insulating layers of the dummy block 112a and the second insulating layers of the dummy block 112b can include a dielectric material including but not limited to silicon oxide, silicon nitride, silicon oxynitride, or any combination thereof. The first dielectric layers of the dummy block 112a and the second dielectric layers of the dummy block 112b can include a dielectric material that is different from the dielectric material of the first insulating layer. For example, the first dielectric layers of the dummy block 112a and the second dielectric layers of the dummy block 112b can include SiN and the first insulating layers of the dummy block 112a and the second insulating layers of the dummy block 112b can include SiO₂. In some implementations, the first separation structure 114 and the second separation structure 116 can be referred to as gate line structures.

As shown in FIG. 1B, a first portion 114-1 of the first separation structure 114 is in contact with the stack 118a of the dummy block 112a and the stack 119a of the dummy block 112b along the Y direction. In some implementations, a first portion 114-1 of the first separation structure 114 includes a first conductive material such as poly-silicon (Poly-Si). In some implementations, the first conductive material of the first portion 114-1 of the first separation structure 114 is in contact with the stack 118a and the stack 119a. In some implementations, the dummy block 112a further includes a stack 118b of the first insulating layers and first conductive layers (e.g., the first conductive layers 132c of FIG. 1C) alternating with each other along the Z direction, and the dummy block 112b further includes a stack 119b of the second insulating layers and second conductive layers (e.g., the second conductive layers 133c of FIG. 1C) alternating with each other along the Z direction. In some implementations, the first conductive layers and the second conductive layers can include a conductive material including, but not limited to W, Co, Cu, Al, TiN, TaN, or any combination thereof. The first portion 114-1 of the first separation structure 114, the stack 118a and the stack 119a are between the stack 118b and the stack 119b along the Y direction.

Each of the core blocks 110 includes a stack 120a of third insulating layers (e.g., the third insulation layers 134a of FIG. 1C) and third dielectric layers stacked on top of each other along the Z direction, and a stack 120b of the third insulating layers and third conductive layers (e.g., the third conductive layers 134b of FIG. 1C) alternating with each other along the Z direction. In some implementations, the third insulating layers can include a same dielectric material (e.g., SiO₂) as the first insulating layers, the third dielectric layers can include a same dielectric material (e.g., SiN) as the first dielectric layers, and third conductive layer can include a same conductive material (e.g., W) as the first conductive layer. In some implementations, the second separation structure 116 is between one or the dummy blocks 112a and 112b and a corresponding core block 110. For example, as shown in FIG. 1B, the second separation structure 116 is between the dummy block 112a and the corresponding core block 110 along the Y direction. In some implementations, the conductive material of the second separation structure 116 is surrounded by a dielectric outer layer 122a.

As shown in FIG. 1B, the semiconductor device 110b also includes a third separation structure 124 extending along the Y direction. In some implementations, the third separation structure 124 can be referred to as a vertical gate line structure. The third separation structure 124 is in contact with the dummy blocks 112a and 112b, the core blocks 110, the second separation structure 116 and a second portion 114-2 of the first separation structure 114 along the X direction. In some implementations, the second separation structure 116 and the third separation structure 124 can include a second conductive material (e.g., poly-Si). In some implementations, the conductive material of a first portion of the third separation structure 124 is surrounded by a dielectric outer layer 122b. In some implementations, the second portion 114-2 of the first separation structure 114 can include a fourth conductive material that is surrounded by a dielectric outer layer 122c. In some implementations, the first conductive material of the first portion 114-1 of the first separation structure 114 can be different from the fourth conductive material of the second portion 114-2 of the first separation structure. For example, the first conductive material can be poly-Si and the fourth conductive material can be WSi. In some implementations, the second separation structure 116, the third separation structure 124, and the second portion 114-2 of the first separation structure 114 can include different materials such as a dielectric material. In some implementations, the second separation structure 116, the third separation structure 124, and the second portion 114-2 of the first separation structure 114 can include a combination of conductive materials such as a combination of W and poly-Si.

As shown in FIG. 1B, the first separation structure 114 and the second separation structure 116 in the first regions 106 and second region 108 are separated by an isolation structure 126. In some implementations, the isolation structure 126 can include a conductive material surrounded by a dielectric material. In some implementations, the isolation structure 126 can include a dielectric material. As shown in FIG. 1B, the second separation structure 116 includes the dielectric outer layer 122b in the second region.

In some implementations, each of the first regions 106 of a corresponding core block 110 can be separate to an array region 107a and a dummy region 107b. In some implementations, the isolation structure 126 is configured to separate the core region 107a and the connection region 108 of the corresponding core block 110. In some implementations, the isolation structure 126 can be used for fabrication process control. For example, the isolation structure 126 is used to fabrication the array region 107a and the connection region 108 separately during a fabrication process. In some implementations, the array region 107a of the corresponding core block 110 includes the stack 120b and the dummy region 107b of the corresponding core block 110 includes a remaining portion of the first region 106 of the corresponding core block 110. In some implementations, the second region 108 of the corresponding core block 110 can be referred to as a connection region.

The stack 118b of the dummy block 112a, the stack 119b of the dummy block 112b, and the stack 120b of the corresponding core block 110 can include an array of channel structures 128 extending along the Z direction. Each of the channel structures 128 can be used to form a string of memory cells coupled in serial along the Z direction. In some implementations, the stack 118a, the stack 119a, and the stack 120a of the semiconductor device 100b can include dummy channel structures 130 (also referred to as dummy memory strings) for process variation control during fabrication and/or for additional mechanical support. In some implementations, the dummy channel structures 130 are in the second region 108. For example, as shown in FIG. 1B, some dummy channel structures 130 can be adjacent to the first separation structure 114 and the second separation structure 116 in the second region 108 to provide mechanical support of the second region during the fabrication process. In some implementations, the dummy channel structures 130 have structures identical or substantially similar to that of the channel structures 128.

The stack 118a and the stack 119a extend into the second region 108 along the X direction and are in contact with the first separation structure 114 along the Y direction. For example, as shown in FIG. 1B, the first conductive material of the first portion 114-1 of the first separation structure 114 is in contact with the stack 118a and the stack 119a along the Y direction in the second region 108, and the first separation structure 114 is between the stack 118a and the stack 119a. In some implementations, the stacks 118a and 119a of the dummy block 112a and 112b is configured to reduce the coupling effect between core blocks 110 of the two adjacent planes 102 of the semiconductor device 100a. The stacks 118a and 119a include alternating insulating layers and dielectric layers which can electrically isolate the core blocks 110 of the two adjacent planes 102.

FIG. 1C illustrates a cross-section view of the example semiconductor device 100b of FIG. 1B along cut line AA′ of FIG. 1B. As shown in FIG. 1C, the dummy blocks 112a and 112b are between the core blocks 110 along the Y direction. The dummy block 112a includes the stacks 118a and 118b. The stack 118a includes the first insulating layers 132a and the first dielectric layers 132b alternating with each other along the Z direction. The stack 118b includes the first insulating layers 132a and first conductive layers 132c alternating with each other along the Z direction. The dummy block 112b includes the stacks 119a and 119b. The stack 119a includes the second insulating layers 133a and the second dielectric layers 133b alternating with each other along the Z direction. The stack 119b includes the second insulating layers 133a and the second conductive layers 133c alternating with each other along the Z direction. The semiconductor device 100b also includes the first separation structure 114 extending along the Z direction. As shown in FIG. 1C, the first separation structure 114 is between the stacks 118a and 119a along the Y direction. In some implementations, each of the core blocks 110 can include the stack 120b of the third insulating layers 134a and the third conductive layers 134b alternating with each other along the Z direction. As shown in FIG. 1C, the stack 120b and the stack 118b are separated by the second separation structure 116 along the Y direction. In some implementations, the stack 120b includes the array of channel structures 128 extending along the Z direction. Each of the channel structures 128 can be used to form a string of memory cells coupled in serial along the Z direction. As shown in FIG. 1C, a length between a first interface 136a and a second interface 136b is at least 3.5 μm to ensure the core blocks are electrically isolated from each other during an operation of the semiconductor device 100b. The first interface 136a is between the stack 118a and the stack 118b along the Y direction, and the second interface 136b is between the stack 119a and the stack 119b along the Y direction.

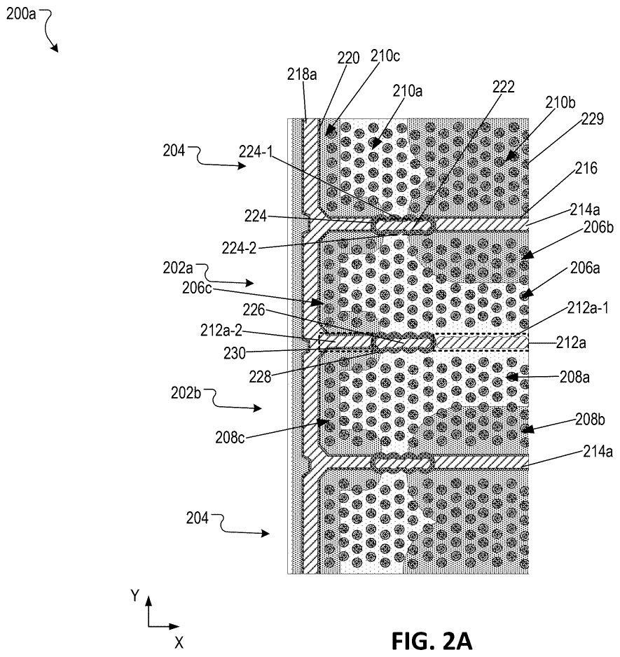

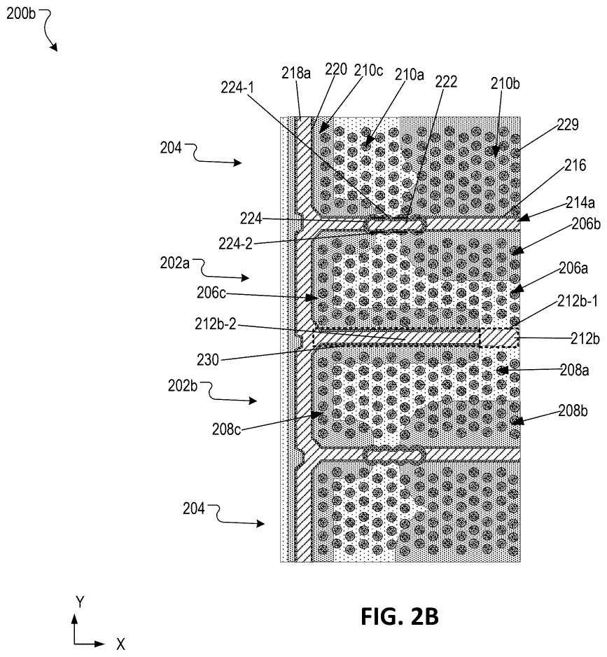

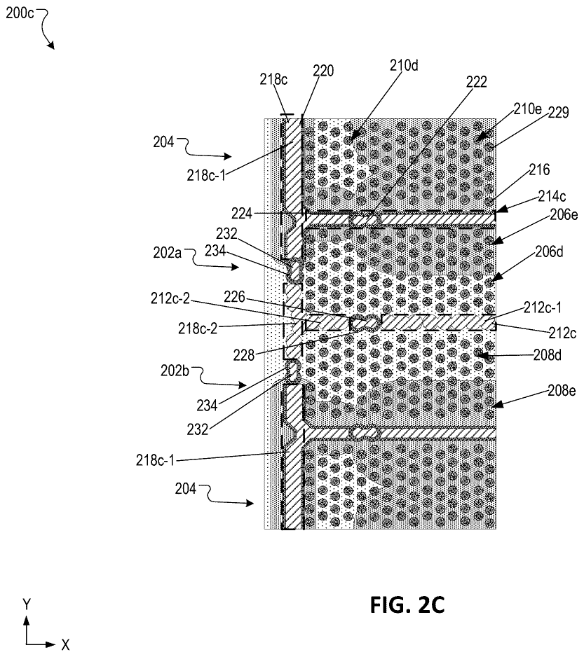

FIG. 2A illustrates a top view of an example semiconductor device 200a. The semiconductor device 200a can be a portion of the semiconductor device 100b of FIG. 1B. The semiconductor device 200a includes two dummy blocks 202a and 202b between core blocks 204 along the Y direction. In some implementations, the two dummy blocks 202a and 202b can be similar to, or same as the dummy blocks 112a and 112b of the semiconductor device 100b of FIG. 1B. In some implementations, the core blocks 204 can be similar to, or same as the core blocks 110 of the semiconductor device 100b of FIG. 1B. It is understood that FIG. 2A is for illustration propose only and the semiconductor device 200a can have any number of the dummy blocks 202a and 202b and core blocks 204.

The dummy block 202a includes stacks 206a and 206b. The stack 206a includes first insulating layers and first dielectric layers alternating with each other along a vertical direction (e.g., the Z direction). The stack 206b includes the first insulating layers and first conductive layers alternating with each other along the Z direction. In some implementations, the stack 206a is similar to, or same as the stack 118a of the semiconductor device 100b of FIG. 1B. The stack 206b is similar to, or same as the stack 118b of the semiconductor device 100b of FIG. 1B.

The dummy block 202b includes stacks 208a and 208b. The stack 208a includes second insulating layers and second dielectric layers alternating with each other along the Z direction. The stack 208b includes the second insulating layers and second conductive layers alternating with each other along the Z direction. In some implementations, the stack 208a is similar to, or same as the stack 119a of the semiconductor device 100b of FIG. 1B. The stack 208b is similar to, or same as the stack 119b of the semiconductor device 100b of FIG. 1B.

Each of the core blocks 204 includes stacks 210a and 210b. The stack 210a includes third insulating layers and third dielectric layers alternating with each other along the Z direction. The stack 210b includes the third insulating layers and third conductive layers alternating with each other along the Z direction. In some implementations, the stack 210a is similar to, or same as the stack 120a of the semiconductor device 100b of FIG. 1B. The stack 210b is similar to, or same as the stack 120b of the semiconductor device 100b of FIG. 1B.

The semiconductor device 200a also includes a first separation structure 212a between the dummy blocks 202a and 202b along a horizontal direction (e.g., the Y direction) perpendicular to the Z direction. The first separation structure 212a extends along a second horizontal direction (e.g., the X direction) perpendicular to the Y direction and the Z direction. As shown in FIG. 2A, a first portion 212a-1 of the first separation structure 212a is in contact with the stack 206a and the stack 208a along the Y direction. In some implementations, as shown in FIG. 2A, along the Y direction, the stack 206a, the stack 208a, and the first portion 212a-1 of the first separation structure 212a are between the stack 206b and the stack 208b. In some implementations, the first portion 212a-1 of the first separation structure 212a includes a first conductive material (e.g., poly-Si). The first conductive material of the first portion 212a-1 of the first separation structure 212a is in contact with the first insulating layers and the first dielectric layers of the stack 206a and the second insulating layers and the second dielectric layers of the stack 208a along the Y direction. In some implementations, the first separation structure 212a is similar to, or same as, the first separation structure 114 of the semiconductor device 100b of FIG. 1B. In some implementations, the first separation structure 212a, the stack of the dummy block 202a, and the stack 208a of the dummy block 202b are configured to electrically isolate the core blocks 204 along the Z direction. In other words, the first separation structure 212a, the stack of the dummy block 202a, and the stack 208a of the dummy block 202b separate the core blocks 204 from each other and enable individual control of each of the core blocks 204. In some implementations, the second portion 212a-2 of the first separation structure 212a can include a fourth conductive material. In some implementations, the fourth conductive material can be a combination of different conductive materials. For example, the fourth conductive material can be a combination of poly-Si and W. In some implementations, second portion 212a-2 of the first separation structure 212a can include a dielectric material (e.g., SiO₂). In some implementations, the fourth conductive material is the same as the first conductive material.

The semiconductor device 200a further includes a second separation structure 214a. The second separation structure 214a extends along the X direction. As shown in FIG. 2A, the second separation structure 214a is between the dummy blocks 202a and 202b and the core blocks 204. In some implementations, the second separation structure 214a includes a second conductive material (e.g., poly-Si) surrounded by a first outer layer 216. In some implementations, the second separation structure 214a is similar to, or same as, the second separation structure 116 of the semiconductor device 100b of FIG. 1B. In some implementations, the first separation structure 212a and the second separation structure 214a can be referred to as gate line structures. In some implementations, the second conductive material can be a combination of different conductive materials. For example, the second conductive material can be a combination of poly-Si and W. In some implementations, the second separation structure 214a can include a dielectric material (e.g., SiO₂). In some implementations, the second conductive material is the same as the first conductive material.

The semiconductor device 200a includes a third separation structure 218a. The third separation structure 218a extends along the Y direction and is in contact with the dummy blocks 202a and 202b, the core blocks 204, the second separation structure 214a and a second portion 212a-2 of the first separation structure 212a along the X direction. As shown in FIG. 2A, the third separation structure 218a can include the second conductive material (e.g., poly-Si). In some implementation, the second conductive material of the third separation structure 218a is connected to the second conductive material of the second separation structure 214a and the fourth conductive material of the second portion 212a-2 of the first separation structure 212a along the X direction. In some implementations, the third separation structure 218a includes a second outer layer 220 that surrounds the second conductive material of the third separation structure 218a. In some implementations, the third separation structure 218a is similar to, or same as, the third separation structure 124 of the semiconductor device 100b of FIG. 1B. In some implementations, the third separation structure 218a can be referred to as vertical gate line structure. In some implementations, the first conductive material is the same as the second conductive material and the fourth conductive material. For example, the first conductive material, the second conductive material, and the third conductive material can all include poly-Si. In some implementations, the first conductive material is different from the second conductive material and the third conductive material. For example, the first conductive material can include Poly-Si, whereas the second conductive material and the third conductive material can include WSi. In some implementations, the third separation structure 218a can include a dielectric material (e.g., SiO₂).

As shown in FIG. 2A, the second separation structure 214a includes a first isolation structure 222 extending along the X direction. The first isolation structure 222 includes a fifth conductive material and a third outer layer 224 that surrounds the fifth conductive material. The first separation structure 212a includes a second isolation structure 226 extending along the X direction. The second isolation structure 226 is between the first portion 212a-1 and the second portion 212a-2 of the first separation structure 212a along the X direction. The second isolation structure 226 includes the fifth conductive material and surrounded by a fourth outer layer 228. In some implementations, a length of the second isolation structure 226 is no greater than a length of the first isolation structure 222 along the X direction. In some implementations, the first isolation structure 222 and the second isolation structure 226 can be used for fabrication process control. In some implementations, the fifth conductive material can include poly-Si, metal silicide or any combination thereof. In some implementations, the first isolation structure 222 and the second isolation structure 226 can include a dielectric material such as SiO₂. The first isolation structure 222 is electrically isolated from the second separation structure 214a and the second isolation structure 226 is electrically isolated from the first separation structure 212a.

As shown in FIG. 2A, the dummy block 202a further includes a stack 206c adjacent to the stack 206a along the X direction, the dummy block 202b further includes a stack 208c adjacent to the stack 208a along the X direction, and the core block 204 further includes a stack 210c adjacent to the stack 210a along the X direction. The stack 206c includes the first insulating layers and fourth conductive layers alternating with each other along the Z direction. The stack 208c includes the second insulating layers and fifth conductive layers alternating with each other along the Z direction. The stack 210c includes the third insulating layers and sixth conductive layers alternating with each other along the Z direction. In some implementations, along the X direction, the stack 210a is between the stack 210b and the stack 210c. In some implementations, the second portion 212a-2 of the first separation structure 212a includes a fifth outer layer 230 that surrounds the fourth conductive material of the second portion 212a-2 of the first separation structure 212a. In some implementations, as shown in FIG. 2A, the second portion 212a-2 of the first separation structure 212a is between the stacks 206c and 208c along the Y direction. The stacks 206c and 208c are in contact with the fifth outer layer 230 of the second portion 212a-2 of the first separation structure 212a.

As shown in FIG. 2A, the stacks 210a, 210b and 210c of the core block 204 are in contact with a first side 224-1 of the third outer layer 224 of the first isolation structure 222 along the Y direction. In some implementations, the stacks 206a, 206b, and 206c of the dummy block 202a are in contact with a second side 224-2 of the third outer layer 224 of the first isolation structure 222 along the Y direction. In some implementations, the stack 210b of the core block 204 includes an array of channel structures 229 extending along the Z direction. Each of the channel structures 229 can be used to form a string of memory cells coupled in serial along the Z direction. The dummy blocks 202a and 202b and the first isolation structure 222 are configured to reduce the coupling effect between the core blocks 204 during a program, read, and erase operation. The first isolation structure 222 electrically isolates the array of memory cells in the stack 210b during program, read, and erase operation of the memory block which enables a precise block selection of the semiconductor device 200a. In other words, the dummy blocks 202a and 202b and the first isolation structure 222 enables individual memory cell array operation in each of the core blocks 204. In some implementations, the stacks 206a and 208a of the dummy blocks 202a and 202b comprises only dielectric material, which reduce a ratio between conductive material and the dielectric material in the dummy blocks 202a and 202b of the two adjacent planes 102. The high ratio of the dielectric material in the dummy blocks 202a and 202b reduces the coupling effect between the core blocks 204 of two adjacent planes 102.

In some implementations, the semiconductor device 200a can include a core block 204 adjacent to the dummy block 202b along the Y direction. The core block 204 and the dummy block 202b are separated by a corresponding second separation structure 214a along the Y direction. In some implementations, as shown in FIG. 2A, the core blocks 204 and the dummy blocks 202a and 202b are mirrored with respect to the first separation structure 212a.

FIG. 2B illustrates a top view of an example semiconductor device 200b. The semiconductor device 200b can be a portion of the semiconductor device 100b of FIG. 1B. In some implementations, the semiconductor device 200b can be similar to the semiconductor device 200a of FIG. 2A, except a first separation structure 212b of the semiconductor device 200b has a different arrangement compared to the first separation structure 212a of the semiconductor device 200a of FIG. 2A.

As shown in FIG. 2B, the first separation structure 212b of the semiconductor device 200b is between the dummy blocks 202a and 202b. The first separation structure 212b extends along the X direction and has a first portion 212b-1 and a second portion 212b-2. The first portion 212b-1 and the second portion 212b-2 of the first separation structure 212b are in contact along the X direction. As shown in FIG. 2B, the first portion 212b-1 of the first separation structure 212b is between the stacks 206a and 208a along the Y direction. In some implementations, the first conductive material of the first portion 212b-1 of the first separation structure 212b is in contact with the stacks 206a and 208a. The second portion 212b-2 of the first separation structure is between the stack 206c and 208c along the Y direction. In some implementations, the fifth outer layer 230 of the second portion 212b-1 of the first separation structure 212b is in contact with the stacks 206c and 208c.

FIG. 2C illustrates a top view of an example semiconductor device 200c. The semiconductor device 200c can be a portion of the semiconductor device 100b of FIG. 1B. The semiconductor device 200c includes two dummy blocks 202a and 202b between core blocks 204 along the Y direction. In some implementations, the two dummy blocks 202a and 202b can be similar to, or same as the dummy blocks 112a and 112b of the semiconductor device 100b of FIG. 1B. In some implementations, the core blocks 204 can be similar to, or same as the core blocks 110 of the semiconductor device 100b of FIG. 1B. It is understood that FIG. 2C is for illustration propose only and the semiconductor device 200c can have any number of the dummy blocks 202a and 202b and core blocks 204.

The dummy block 202a includes stacks 206d and 206e. The stack 206d includes first insulating layers and the dielectric layers alternating with each other along a vertical direction (e.g., the Z direction). The stack 206e includes the first insulating layers and first conductive layers alternating with each other along the Z direction. The dummy block 202b includes stacks 208d and 208e. The stack 208d includes second insulating layers and second dielectric layers alternating with each other along the Z direction. The stack 208e includes the second insulating layers and second conductive layers alternating with each other along the Z direction. Each of the core blocks 204 includes stacks 210d and 210e. The stack 210d includes third insulating layers and third dielectric layers alternating with each other along the Z direction. The stack 210e includes the third insulating layers and third conductive layers alternating with each other along the Z direction. In some implementations, as shown in FIG. 2C, the stack 210e surrounds the stack 210d in a plane perpendicular to the Z direction.

The semiconductor device 200c also includes a first separation structure 212c between the dummy blocks 202a and 202b along a horizontal direction (e.g., the Y direction) perpendicular to the Z direction. The first separation structure 212c extends along the X direction. As shown in FIG. 2C, the first separation structure 212c is in contact with the stack 206a and the stack 208a along the Y direction. In some implementations, as shown in FIG. 2C, along the Y direction, the stack 206d, the stack 208e, and the first separation structure 212c are between the stack 206e and the stack 208e.

The semiconductor device 200c further includes a second separation structure 214c. The second separation structure 214c extends along the X direction. As shown in FIG. 2C, the second separation structure 214c is between the dummy blocks 202a and 202b. In some implementations, the second separation structure 214c includes a first outer layer 216. In some implementations, as shown in FIG. 2C, the first outer layer 216 is in contact with the stack 210e of the core block 204 and the stack 206e of the dummy block 202a along the Y direction. In some implementations, the first separation structure 212c and the second separation structure 214c can be referred to as gate line structures.

The semiconductor device 200c includes a third separation structure 218c. The third separation structure 218c extends along the Y direction and is in contact with the dummy blocks 202a and 202b, the core blocks 204, the second separation structure 214c and the first separation structure 212c along the X direction. As shown in FIG. 2C, the third separation structure 218c includes a first portion 218c-1 and a second portion 218c-2. In some implementations, the first portion 218c-1 of the third separation structure 218c includes the second conductive material and the second portion 218c-2 of the third separation structure 218c includes a third conductive material. In some implementations, the first portion 218c-1 of the third separation structure 218c includes a second outer layer 220 that surrounds the second conductive material of the first portion 218c-1 of the third separation structure 218c. In some implementations, the third separation structure 218c can be referred to as vertical gate line structure.

As shown in FIG. 2C, the second separation structure 214c includes a first isolation structure 222 extending along the X direction. In some implementations, the first isolation structure 222 includes the fifth conductive material and a third outer layer 224 that surrounds the fifth conductive material. The first separation structure 212c includes a second isolation structure 226 extending along the X direction. The second isolation structure 226 includes the fifth conductive material that is surrounded by a fourth outer layer 228. In some implementations, the fifth conductive material can include poly-Si, metal silicide or any combination thereof. In some implementations, the first isolation structure 222 and the second isolation structure 226 can include a dielectric material such as SiO₂. The first isolation structure 222 is electrically isolated from the second separation structure 214c and the second isolation structure 226 is electrically isolated from the first separation structure 212c.

The third separation structure 218c includes at least two third isolation structures 232 that extend along the Y direction. Each of the at least two third isolation structures 232 includes the fifth conductive material surrounded by a sixth outer layer 234. In some implementations, each of the stacks 206d and 208d is in contact with a corresponding third isolation structure 232 of the at least two third isolation structures 232 along the Y direction. In some implementations, the third conductive material of the second portion 218c-2 of the third separation structure 218c is in contact with the stacks 206d and 208d along the X direction. In some implementations, the second portion 218c-2 of the third separation structure 218c is between two adjacent third isolation structures 232 in corresponding dummy blocks 202a and 202b along the Y direction. For example, both the first conductive material and the third conductive material can be poly-Si. In some implementations, the fifth conductive material can include poly-Si, metal silicide or any combination thereof. In some implementations, the at least two third isolation structures 232 can include a dielectric material such as SiO₂. The at least two third isolation structures 232 are electrically isolated from the third separation structure 218c.

In some implementations, as shown in FIG. 2C, the second isolation structure 226 separates the first separation structure 212c into two portions 212c-1 and 212c-2 along the Y direction. The fourth conductive material of the second portion 212c-2 of the first separation structure 212c is in contact with the third conductive material of the second portion 218c-2 of the third separation structure 218c along the X direction. In some implementations, the first portion 212c-1 and the second portion 212c-2 of the first separation structure 212c are in contact with the stacks 206d and 208d along the Y direction. In some implementations, the third conductive material is the same as the first conductive material. In some implementations, the third conductive material is the same as the fourth conductive material.

The stack 210e of the core block 204 includes an array of channel structures 229 extending along the Z direction. Each of the channel structures 229 can be used to form a string of memory cells coupled in serial along the Z direction. In some implementations, the first isolation structure 222, the second isolation structure 226, and the two third isolation structures 232 can be used for fabrication process control. In some implementations, the first isolation structure 222, the second isolation structure 226, the two third isolation structures 232, and the stacks 206d and 208d are configured to reduce the coupling effect between the core blocks 204 during device operation. The stacks 206d and 208d electrically isolates the array of memory cells in the stack 210e during program, read, and erase operation of the memory block which enables a precise block selection of the semiconductor device 200a. In other words, the dummy blocks 202a and 202b enables individual memory cell array operation in each of the core blocks 204. In some implementations, the stacks 206d and 208d of the dummy blocks 202a and 202b comprises only dielectric material. The dielectric material in the dummy blocks 202a and 202b reduces the coupling effect between the core blocks 204 of two adjacent planes 102.

It is understood examples of the first conductive material, the second conductive material, the third conductive material, the fourth conductive material, and the fifth conductive material are for illustration purpose only, and the first conductive material, the second conductive material, the third conductive material, the fourth conductive material, and the fifth conductive material can include any conductive material such as poly-Si, metal silicide, or any combinations thereof.

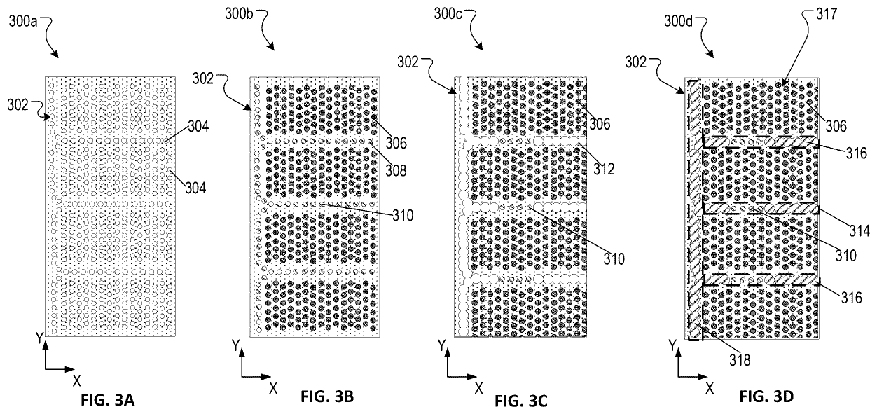

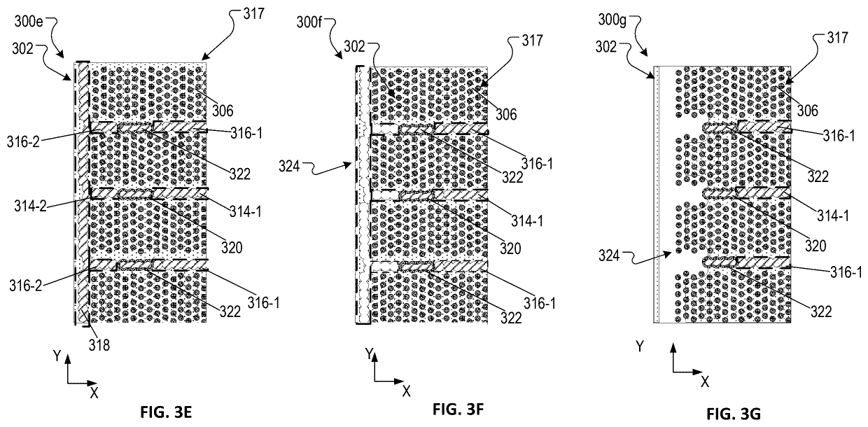

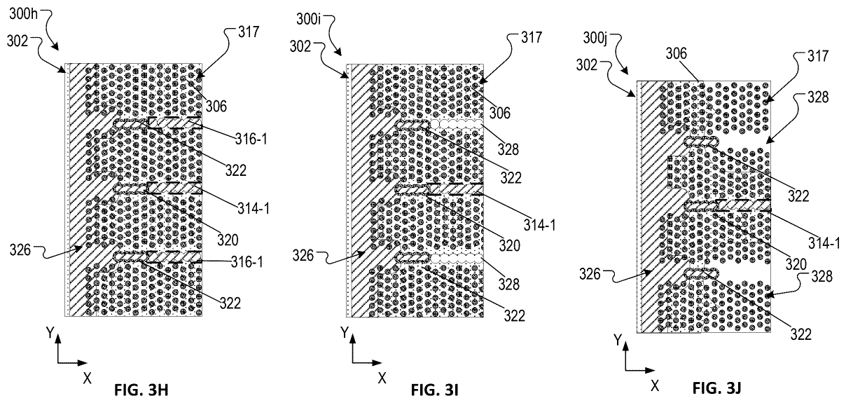

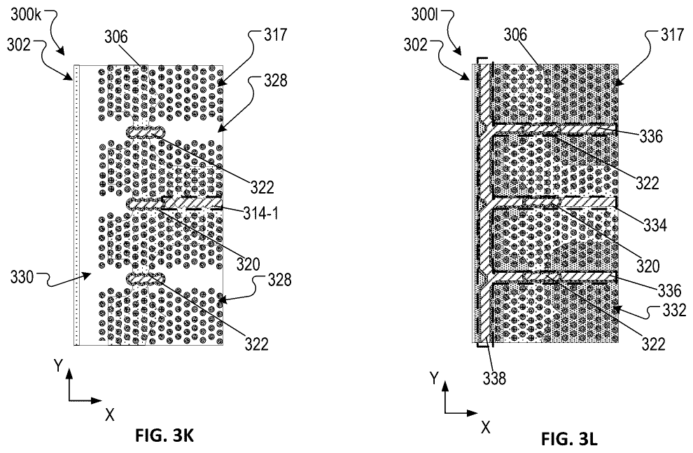

FIGS. 3A-3L illustrate an example process of fabricating a semiconductor device, such as the semiconductor device 200a as illustrated in FIG. 2A. FIGS. 3A-3N show cross-sectional views of example semiconductor structures at various stages of the fabrication process.

As shown in FIG. 3A, a semiconductor structure 300a is formed. The semiconductor structure 300a includes a stack 302 of insulating layers and dielectric layers alternating with each other along a vertical direction (e.g., the Z direction). The semiconductor structure 300a includes first holes 304, which can be formed by etching a portion of the stack 302 along the Z direction through an etching process.

As shown in FIG. 3B, a semiconductor structure 300b is formed. The semiconductor structure 3b includes channel structures 306, first filled holes 308, and second filled holes 310. The channel structures 306 can be formed by filling dielectric material, semiconductor material, and conductive material in a first portion of the first holes 304. The first filled holes 308 can be formed by filling a first sacrificial material in a second portion of the first holes 304. The second filled holes 310 can be formed by filling a second sacrificial material in a second portion of the first holes 304.

As shown in FIG. 3C, a semiconductor structure 300c is formed. The semiconductor structure 300c includes a first space 312. The first space 312 can be formed by removing the first sacrificial material in the first filled holes 308 and expanding the first filled holes 308 through an etching process so that the second portion of the first holes 304 are connected to each other.

As shown in FIG. 3D, a semiconductor structure 300d is formed. The semiconductor structure 300d includes a first semiconductor structure 314, second semiconductor structures 316, and a third semiconductor structure 318. The first semiconductor structure 314, the second semiconductor structures 316, and the third semiconductor structure 318 can be formed by filling the first space 312 with a semiconductor material. As shown in FIG. 3D, the first semiconductor structure 314 and the second semiconductor structures 316 extend along a horizontal direction (e.g., the X direction) perpendicular to the Z direction. In some implementations, as shown in FIG. 3D, the first semiconductor structure 314 is between two adjacent second semiconductor structures 316 along the Y direction. The first semiconductor structure 314 and the second semiconductor structures 316 separated the channel structures 306 into one or more blocks 317. The third semiconductor structure 318 extends along a second horizontal direction (e.g., the Y direction) perpendicular to the X direction and the Z direction. As shown in FIG. 3D, the first semiconductor structure 314 and the second semiconductor structures 316 are connected to the third semiconductor structure 318 along the X direction.

As shown in FIG. 3E, a semiconductor structure 300e is formed. The semiconductor structure 300e includes a first isolation structure 320 and second isolation structures 322. The first isolation structure 320 and the second isolation structures 322 can be formed by removing the second sacrificial material and expanding the second filled holes 310 along the X direction to form second spaces. The first isolation structure 320 can be formed by filling a conductive material surrounded by a dielectric material in a corresponding second space in the first semiconductor structure 314. The second isolation structures 322 can be formed by filling a conductive material surrounded by a dielectric material in corresponding second spaces in the second semiconductor structure 316. As shown in FIG. 3E, the first isolation structure 320 separated the first semiconductor structure 314 into two portions 314-1 and 314-2. Each of the second isolation structures 322 separate a corresponding second semiconductor structure 316 into two portions 316-1 and 316-2. The second portion 314-2 of the first semiconductor structure and the second portions 316-2 of the second semiconductor structures 316-2 are connected to the third semiconductor structure 318 along the X direction.

FIG. 3F illustrates a semiconductor structure 300f, which can be formed by etching the semiconductor material in the second portion 314-2 of the first semiconductor structure 314, the second portions 314-2 of the second semiconductor structures 316, and the third semiconductor structure 318 to form a third space 324.

FIG. 3G illustrates a semiconductor structure 300g, which can be formed by filling an etch solution into the third space 324 and etching a portion of the dielectric layers of the stack 302 adjacent to the third space 324.

FIG. 3H illustrates a semiconductor structure 300h, which can be formed by filling a third sacrificial material into the third space 324 to form a sacrificial structure 326.

FIG. 3I illustrates a semiconductor structure 300i, which can be formed by etching the semiconductor material in the first portions 316-1 of the second semiconductor structures to form fourth spaces 328.

FIG. 3J illustrates a semiconductor structure 300j, which can be formed by filling an etch solution into the fourth spaces 328 and etching a portion of the dielectric layers of the stack 302 adjacent to the fourth spaces 328.

FIG. 3K illustrates a semiconductor structure 300k, which can be formed by etching the third sacrificial material of the sacrificial structure 326 to form a fifth space 330.

FIG. 3L illustrates a semiconductor structure 300l, which can be formed by filling a conductive material into a first portion of the fourth spaces 328 and a first portion of the fifth space 330 to form conductive layers 332. The first portion of the fourth spaces 328 and the first portion of the fifth space 330 include etched dielectric layers of the stack 302. The semiconductor structure 300l also includes a first separation structure 334, second separation structures 336, and a third separation structure 338, which can be formed by filling a remaining portion of the fourth spaces 328 and a remaining portion of the fifth space with a semiconductor material surrounded by a dielectric material.

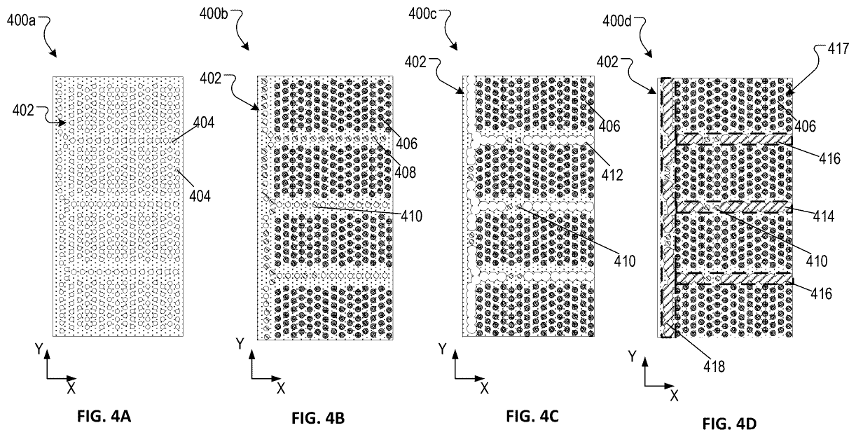

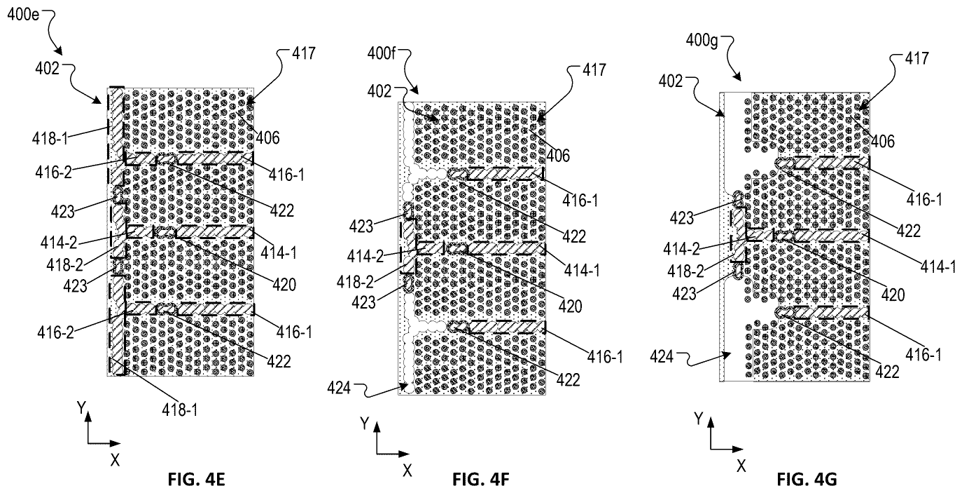

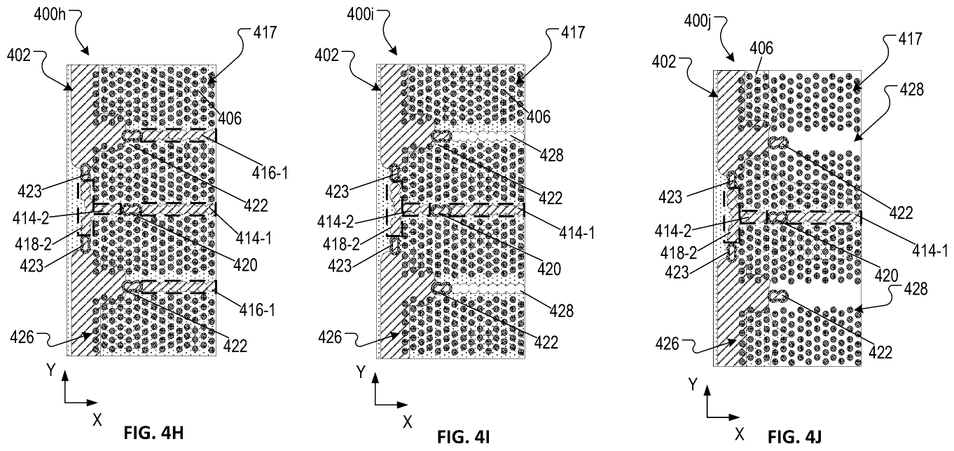

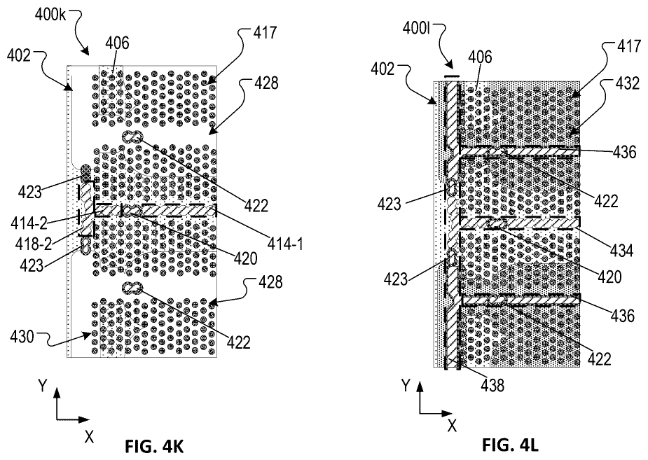

FIGS. 4A-4L illustrate an example process of fabricating a semiconductor device, such as the semiconductor device 200c as illustrated in FIG. 2C. FIGS. 4A-4L show cross-sectional views of example semiconductor structures at various stages of the fabrication process.

As shown in FIG. 4A, a semiconductor structure 400a is formed. The semiconductor structure 400a includes a stack 402 of insulating layers and dielectric layers alternating with each other along a vertical direction (e.g., the Z direction). The semiconductor structure 400a includes first holes 404, which can be formed by etching a portion of the stack 402 along the Z direction through an etching process.

As shown in FIG. 4B, a semiconductor structure 400b is formed. The semiconductor structure 400b includes channel structures 406, first filled holes 408, and second filled holes 410. The channel structures 406 can be formed by forming a channel structure in a first portion of the first holes 404. The first filled holes 408 can be formed by filling a first sacrificial material in a second portion of the first holes 404. The second filled holes 410 can be formed by filling a second sacrificial material in a second portion of the first holes 404.

As shown in FIG. 4C, a semiconductor structure 400c is formed. The semiconductor structure 400c includes a first space 412. The first space 412 can be formed by removing the first sacrificial material in the first filled holes 408 and expanding the first filled holes 408 through an etching process so that the second portion of the first holes 404 are connected to each other.

As shown in FIG. 4D, a semiconductor structure 400d is formed. The semiconductor structure 400d includes a first semiconductor structure 414, second semiconductor structures 416, and a third semiconductor structure 418. The first semiconductor structure 414, the second semiconductor structures 416, and the third semiconductor structure 418 can be formed by filling the first space 412 with a semiconductor material. As shown in FIG. 4D, the first semiconductor structure 414 and the second semiconductor structures 416 extend along a horizontal direction (e.g., the X direction) perpendicular to the Z direction. In some implementations, as shown in FIG. 4D, the first semiconductor structure 414 is between two adjacent second semiconductor structures 416 along the Y direction. The first semiconductor structure 414 and the second semiconductor structures 416 separated the channel structures 406 into one or more blocks 417. The third semiconductor structure 418 extends along a second horizontal direction (e.g., the Y direction) perpendicular to the X direction and the Z direction. As shown in FIG. 4D, the first semiconductor structure 414 and the second semiconductor structures 416 are connected to the third semiconductor structure 418 along the X direction.

As shown in FIG. 4E, a semiconductor structure 400e is formed. The semiconductor structure 400e includes a first isolation structure 420, second isolation structures 422, and at least two third isolation structures 423. The first isolation structure 420, the second isolation structures 422, and the at least two third isolation structures 423 can be formed by removing the second sacrificial material and expanding the second filled holes 410 along the X direction to form second spaces. The first isolation structure 420 can be formed by filling a conductive material surrounded by a dielectric material in a corresponding second space in the first semiconductor structure 414. The second isolation structures 422 can be formed by filling a conductive material surrounded by a dielectric material in corresponding second spaces in the second semiconductor structure 416. The at least two third isolation structures 423 can be formed by filling a conductive material surrounded by a dielectric material in corresponding second spaces in the third semiconductor structure 418. As shown in FIG. 4E, the first isolation structure 420 separated the first semiconductor structure 414 into two portions 414-1 and 414-2. Each of the second isolation structures 422 separate a corresponding second semiconductor structure 416 into two portions 416-1 and 416-2. The second portion 414-2 of the first semiconductor structure 414 is between two adjacent third isolation structures 423 along the Y direction. The two adjacent third isolation structures 423 separates the third semiconductor structure 418 into two portions 418-1 and 418-2. The second portion 418-2 of the third semiconductor structure 418 is between the two adjacent third isolation structures 423 along the Y direction. The second portion 414-2 of the first semiconductor structure is connected to the second portion 418-2 of the third semiconductor structure 418 along the X direction. The second portions 416-2 of the second semiconductor structures 416 are connected to the first portion 418-1 of the third semiconductor structure 418 along the X direction.

FIG. 4F illustrates a semiconductor structure 400f, which can be formed by etching the semiconductor material in the second portion 414-2 of the first semiconductor structure 414, the second portions 416-2 of the second semiconductor structures 416, and the first portion 418-1 of the third semiconductor structure 418 to form a third space 424.

FIG. 4G illustrates a semiconductor structure 400g, which can be formed by filling an etch solution into the third space 424 and etching a portion of the dielectric layers of the stack 402 adjacent to the third space 424.

FIG. 4H illustrates a semiconductor structure 400h, which can be formed by filling a third sacrificial material into the third space 424 to form a sacrificial structure 426.

FIG. 4I illustrates a semiconductor structure 400i, which can be formed by etching the semiconductor material in the first portions 416-1 of the second semiconductor structures to form fourth spaces 428.

FIG. 4J illustrates a semiconductor structure 400j, which can be formed by filling an etch solution into the fourth spaces 428 and etching a portion of the dielectric layers of the stack 402 adjacent to the fourth spaces 428.

FIG. 4K illustrates a semiconductor structure 400k, which can be formed by etching the third sacrificial material of the sacrificial structure 426 to form a fifth space 430.

FIG. 4L illustrates a semiconductor structure 400l, which can be formed by filling a conductive material into a first portion of the fourth spaces 428 and a first portion of the fifth space 430 to form conductive layers 432. The first portion of the fourth spaces 428 and the first portion of the fifth space 430 include etched dielectric layers of the stack 402. The semiconductor structure 400l also includes a first separation structure 434, second separation structures 436, and a third separation structure 438, which can be formed by filling a remaining portion of the fourth spaces 428 and a remaining portion of the fifth space with a semiconductor material surrounded by a dielectric material.

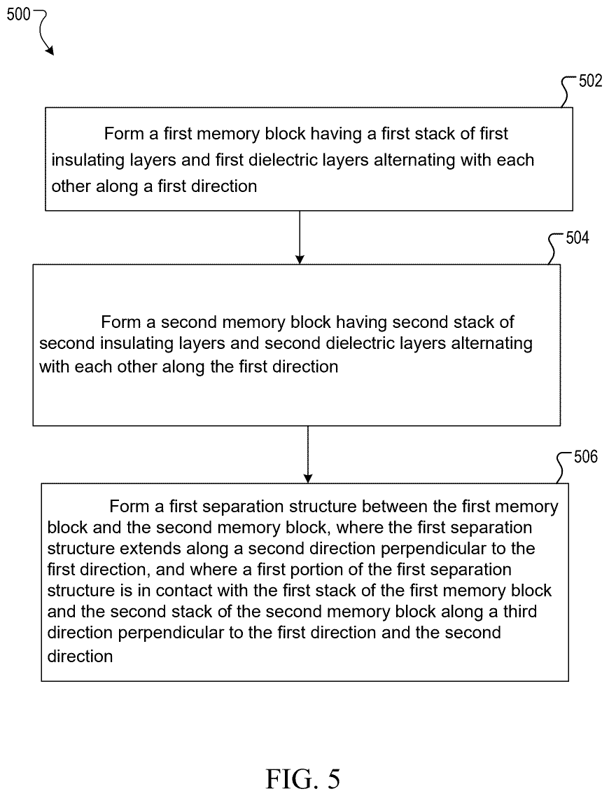

FIG. 5 illustrates a flow chart of an example process 500. The process 500 can be performed to form a semiconductor device (e.g., the semiconductor device 200a illustrated by FIG. 2A or the semiconductor device 200c illustrated by FIG. 2C). The process 500 can be described in view of FIG. 3A-3L or FIG. 4A-4L. The process 500 can include one or more steps of the fabrication process of forming the semiconductor structures in FIG. 3A-3L or FIG. 4A-4L. It is understood that the operations shown in process 500 are not exhaustive and that other operations can be performed as well before, after, or between any of the illustrated operations. Further, some of the operations may be performed simultaneously, or in a different order than shown in FIG. 5.

At operation 502, a first memory block (e.g., the dummy block 202a of FIG. 2A) having a first stack (e.g., the stack 206a of FIG. 2A) of first insulating layers and first dielectric layers alternating with each other along a first direction (e.g., the Z direction) is formed.

At operation 504, a second memory block (e.g., the dummy block 202b of FIG. 2A) having second stack (e.g., the stack 208a of FIG. 2A) of second insulating layers and second dielectric layers alternating with each other along the first direction is formed.

At operation 506, a first separation structure (e.g., the first separation structure 212a of FIG. 2A) between the first memory block and the second memory block is formed. The first separation structure extends along a second direction (e.g., the X direction) perpendicular to the first direction, and where a first portion (e.g., the first portion 212a-1 of FIG. 2A) of the first separation structure is in contact with the first stack of the first memory block and the second stack of the second memory block along a third direction (e.g., the Y direction) perpendicular to the first direction and the second direction.

In some implementations, the method further includes forming a third memory block (e.g., the core blocks 204 of FIG. 2A) having a fifth stack (e.g., the stack 210b of FIG. 2A) of third insulating layers and third conductive layers alternating with each other along the first direction, and a sixth stack (e.g., the stack 210a of FIG. 2A) of the third insulating layers and third dielectric layers stacked on top of each other along the first direction; and forming a second separation structure (e.g., the second separation structure 214a of FIG. 2A) extending along the second direction, where the second separation structure is between the first memory block and the third memory block.

In some implementations, the method further includes providing a first block structure corresponding to the first memory block, a second block structure corresponding to the second memory block, and a third block structure corresponding to the third memory block, the first block structure, the second block structure, and the third block structure including alternating dielectric layers and isolating layers, where the first block structure is between the second block structure and the third block structure along the third direction, where the first block structure and the second block structure are separated by a first semiconductor structure (e.g., the first semiconductor structure 314 of FIG. 3D), and where the first block structure and the third block structure are separated by a second semiconductor structure (e.g., the second semiconductor structure 316 of FIG. 3D); forming a second isolation structure (e.g., first isolation structure 320 of FIG. 3E) extending along the second direction in the first semiconductor structure; forming a first isolation structure (e.g., the second isolation structures 322 of FIG. 3E) extending along the second direction in the second semiconductor structure; removing a first portion (e.g., the first portion 316-1 of the second semiconductor structure 316 of FIG. 3E) of the second semiconductor structure to form a first trench (e.g., the fourth spaces 328 of FIG. 3I), where the first portion of the semiconductor structure is in contact with a first end of the first isolation structure along the second direction; filling an etching solution into the first trench to etch a portion of the dielectric layers of the first block structure and a portion of the dielectric layers of the third block structure to form a first space; filling a fifth conductive material in the first space; and filling the first trench with a second conductive material surrounded by a dielectric material.

In some implementations, the method further includes forming a third semiconductor structure (e.g., the third semiconductor structure 318 of FIG. 3D) extending along the third direction, where the third semiconductor structure is in contact with the first block structure, the second block structure, the third block structure, the first semiconductor structure, and a second portion of the second semiconductor structure along the second direction.

In some implementations, the method includes etching the third semiconductor structure, the second portion of the second semiconductor structure in contact with the third semiconductor structure, and a portion of the first semiconductor structure in contact with the third semiconductor structure to form a second trench (e.g., the third space 324 of FIG. 3F); filling an etching solution into the second trench to etch a portion of the dielectric layers of the first block structure and a portion of the dielectric layers of the third block structure to form a second space (e.g., the fifth space 330 of FIG. 3K); filling the fifth conductive material in the second space; and filling the second trench with the second conductive material surrounded by the dielectric material.

In some implementations, the method includes forming at least two third isolation structures (e.g., the at least two third isolation structures 423 of FIG. 4F) extending along the third direction in the third semiconductor structure, where each of the first block structure and the second block structure is in contact with a corresponding third isolation structure of the at least two third isolation structures along the second direction; etching a portion of the third semiconductor structure and the second portion of the second semiconductor structure to form a third trench (e.g., the third space 424 of FIG. 4F); filling an etching solution into the third trench to etch a portion of the dielectric layers of the first block structure and a portion of the dielectric layers of the third block structure to form a third space (e.g., the fifth space 430 of FIG. 4K); filling the fifth conductive material in the third space; and filling the third trench with the second conductive material surrounded by the dielectric material.

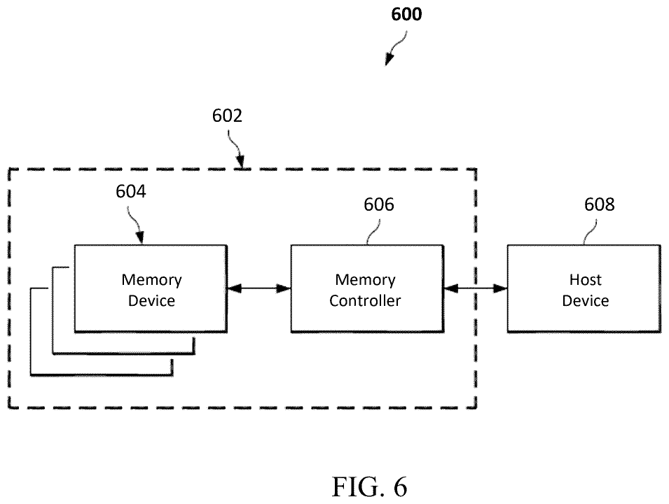

FIG. 6 illustrates a block diagram of an example system 600. The system 600 can have one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 6, the system 600 can include a host device 608 and a memory system 602 having one or more memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more memory devices 604.

A memory device 604 can be any memory device disclosed in the present disclosure, such as a memory device (e.g., a NAND Flash memory) as shown in FIGS. 1B-1C and FIGS. 2A-2C. Memory controller 606 (a.k.a., a controller circuit) is coupled to memory device 604 and host device 608. Consistent with implementations of the present disclosure, memory device 604 can include a plurality of conductive interconnections through a cover layer that are in contact with conductive pads in a conductive pad layer, and memory controller 606 can be coupled to memory device 604 through at least one of the plurality of conductive interconnections. Memory controller 606 is configured to control memory device 604. For example, memory controller 606 may be configured to operate a plurality of channel structures via word lines. Memory controller 606 can manage data stored in memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of memory device 604, such as read, erase, and program (or write) operations. Memory controller 606 can also be configured to manage various functions with respect to the data stored or to be stored in memory device 604 including, but not limited to bad-block management, garbage collection, logical-to-physical address conversion, wear leveling, etc. In some implementations, memory controller 606 is further configured to process error correction codes (ECCs) with respect to the data read from or written to memory device 604. Any other suitable functions may be performed by memory controller 606 as well, for example, formatting memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,. +−0.10%, +−0.20%, or. +−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What the claim is:

1. A semiconductor device, comprising:
a first memory block having a first stack of first insulating layers and first dielectric layers alternating with each other along a first direction;
a second memory block having a second stack of second insulating layers and second dielectric layers alternating with each other along the first direction; and
a first separation structure between the first memory block and the second memory block,
wherein the first separation structure extends along a second direction perpendicular to the first direction, and
wherein a first portion of the first separation structure is in contact with the first stack of the first memory block and the second stack of the second memory block along a third direction perpendicular to the first direction and the second direction.

2. The semiconductor device of claim 1, wherein the first memory block further comprises a third stack of the first insulating layers and first conductive layers alternating with each other along the first direction,
wherein the second memory block further comprises a fourth stack of the second insulating layers and second conductive layers alternating with each other along the first direction, and
wherein the first stack, the first separation structure, and the second stack are between the third stack of the first memory block and the fourth stack of the second memory block along the third direction.

3. The semiconductor device of claim 1, wherein the first portion of the first separation structure comprises a first conductive material, wherein the first conductive material is in contact with the first stack of the first memory block and the second stack of the second memory block.

4. The semiconductor device of claim 1, further comprising:
a third memory block having a fifth stack of third insulating layers and third conductive layers alternating with each other along the first direction, and a sixth stack of the third insulating layers and third dielectric layers stacked on top of each other along the first direction; and
a second separation structure extending along the second direction,
wherein the second separation structure is between the first memory block and the third memory block.

5. The semiconductor device of claim 4, further comprising:
a third separation structure extending along the third direction, wherein the third separation structure is in contact with the first memory block, the second memory block, the third memory block, the second separation structure, and a second portion of the first separation structure along the second direction.

6. The semiconductor device of claim 5, wherein the second separation structure comprises a second conductive material surrounded by a first outer layer, and wherein a first portion of the third separation structure comprises the second conductive material surrounded by a second outer layer.

7. The semiconductor device of claim 4, wherein the second separation structure comprises a first isolation structure extending along the second direction.

8. The semiconductor device of claim 7, wherein the first separation structure comprises a second isolation structure extending along the second direction, wherein the second isolation structure is between the first portion and a second portion of the first separation structure, and
wherein a length of the second isolation structure is no greater than a length of the first isolation structure along the second direction.

9. The semiconductor device of claim 7, wherein the third memory block further comprises:
a seventh stack of the third insulating layers and fourth conductive layers alternating with each other along the first direction, wherein the sixth stack is between the fifth stack and the seventh stack along the second direction, and
wherein the fifth stack, the sixth stack and the seventh stack are in contact with the first isolation structure.

10. The semiconductor device of claim 6, wherein the third separation structure comprises at least two third isolation structures extending along the third direction, and
wherein each of the first stack and the second stack is in contact with a corresponding third isolation structure of the at least two third isolation structures along the second direction.

11. The semiconductor device of claim 10, wherein a second portion of the third separation structure comprises a third conductive material, the second portion of the third separation structure is between two adjacent third isolation structures in the first memory block and the second memory block along the third direction
wherein the first stack and the second stack are in contact with the third conductive material along the second direction.

12. The semiconductor device of claim 10, wherein the second portion of the first separation structure comprises a fourth conductive material, wherein the fourth conductive material is in contact with the first stack of the first memory block and the second stack of the second memory block.

13. The semiconductor device of claim 12, wherein the second portion of the first separation structure is between the first stack and the second stack along the third direction.

14. A method of forming a semiconductor device, the method comprising:
forming a first memory block having a first stack of first insulating layers and first dielectric layers alternating with each other along a first direction;
forming a second memory block having second stack of second insulating layers and second dielectric layers alternating with each other along the first direction; and
forming a first separation structure between the first memory block and the second memory block,
wherein the first separation structure extends along a second direction perpendicular to the first direction, and
wherein a first portion of the first separation structure is in contact with the first stack of the first memory block and the second stack of the second memory block along a third direction perpendicular to the first direction and the second direction.

15. The method of claim 14, further comprising:
forming a third memory block having a fifth stack of third insulating layers and third conductive layers alternating with each other along the first direction, and a sixth stack of the third insulating layers and third dielectric layers stacked on top of each other along the first direction; and
forming a second separation structure extending along the second direction, wherein the second separation structure is between the first memory block and the third memory block.

16. The method of claim 15, wherein the method further comprises:
providing a first block structure corresponding to the first memory block, a second block structure corresponding to the second memory block, and a third block structure corresponding to the third memory block, the first block structure, the second block structure, and the third block structure comprising alternating dielectric layers and isolating layers,
wherein the first block structure is between the second block structure and the third block structure along the third direction,
wherein the first block structure and the second block structure are separated by a first semiconductor structure, and
wherein the first block structure and the third block structure are separated by a second semiconductor structure;
forming a second isolation structure extending along the second direction in the first semiconductor structure;
forming a first isolation structure extending along the second direction in the second semiconductor structure;
removing a first portion of the second semiconductor structure to form a first trench, wherein the first portion of the second semiconductor structure is in contact with a first end of the first isolation structure along the second direction;
filling an etching solution into the first trench to etch a portion of the dielectric layers of the first block structure and a portion of the dielectric layers of the third block structure to form a first space;
filling a fifth conductive material in the first space; and
filling the first trench with a second conductive material surrounded by a dielectric material.

17. The method of claim 16, further comprising:
forming a third semiconductor structure extending along the third direction, wherein the third semiconductor structure is in contact with the first block structure, the second block structure, the third block structure, the first semiconductor structure, and a second portion of the second semiconductor structure along the second direction.

18. The method of claim 17, wherein the method comprises:
etching the third semiconductor structure, the second portion of the second semiconductor structure in contact with the third semiconductor structure, and a portion of the first semiconductor structure in contact with the third semiconductor structure to form a second trench;
filling an etching solution into the second trench to etch a portion of the dielectric layers of the first block structure and a portion of the dielectric layers of the third block structure to form a second space;
filling the fifth conductive material in the second space; and
filling the second trench with the second conductive material surrounded by the dielectric material.

19. The method of claim 17, wherein the method comprises:
forming at least two third isolation structures extending along the third direction in the third semiconductor structure, wherein each of the first block structure and the second block structure is in contact with a corresponding third isolation structure of the at least two third isolation structures along the second direction;
etching a portion of the third semiconductor structure and the second portion of the second semiconductor structure to form a third trench;
filling an etching solution into the third trench to etch a portion of the dielectric layers of the first block structure and a portion of the dielectric layers of the third block structure to form a third space;
filling the fifth conductive material in the third space; and
filling the third trench with the second conductive material surrounded by the dielectric material.

20. A memory system, comprising:
a memory device; and
a memory controller coupled to the memory device and configured to control the memory device,
wherein the memory device comprises:
a first memory block having a first stack of first insulating layers and first dielectric layers alternating with each other along a first direction;
a second memory block having second stack of second insulating layers and second dielectric layers alternating with each other along the first direction; and
a first separation structure between the first memory block and the second memory block,
wherein the first separation structure extends along a second direction perpendicular to the first direction, and
wherein a first portion of the first separation structure is in contact with the first stack of the first memory block and the second stack of the second memory block along a third direction perpendicular to the first direction and the second direction.
